(19) United States
(12) Patent Application Publication
(10) Pub. No.: US 2025/0074815 A1
(43) Pub. Date: Mar. 6, 2025

(54) GLASS DISPLAY COVER WITH REALISTIC HAPTIC TEXTURE AND MANUFACTURING METHOD THEREOF

(71) Applicant: CHENFENG OPTRONICS CORPORATION, Taichung City (TW)

(72) Inventors: CHING-FANG WONG, Taichung City (TW); YU-WEI LIU, Taichung City (TW); WEI-LUN ZENG, Taichung City (TW); BANG-JIN YOU, Taichung City (TW)

(73) Assignee: CHENFENG OPTRONICS CORPORATION, Taichung City (TW)

(21) Appl. No.: 18/800,434

(22) Filed: Aug. 12, 2024

(30) Foreign Application Priority Data
Aug. 28, 2023 (TW) 112132362

(51) Int. Cl. C03C 17/00; B41M 1/12; B41M 1/34; B41M 3/00; B41M 7/00; C03C 17/25; C03C 17/32; H05K 5/03

(52) U.S. Cl. CPC C03C 17/007; B41M 1/12; B41M 1/34; B41M 3/003; B41M 7/009; C03C 17/25; C03C 17/32; H05K 5/03

(57) ABSTRACT

A glass display cover with realistic haptic texture and a manufacturing method thereof are disclosed. The glass display cover is for being installed at one side of a display module. The glass display cover includes a glass substrate, a pattern layer, a pattern-highlighting layer, and a textured layer. The glass substrate is installed at the side of the display module. The pattern layer is formed by color layers stacked on the glass substrate. The pattern-highlighting layer is on a side of the pattern layer facing away from the glass substrate. The pattern-highlighting layer is made of a mixture of a white ink and a diluent. The textured layer is formed at a revere side of the glass substrate. The textured layer is made of a solvent material mixed with particles. The manufacturing method includes forming the layers. The textured layer endows the glass display cover with added qualitative value.

### BACKGROUND OF THE INVENTION

### 1. Technical Field

The present invention relates to glass display covers, and more particularly to a glass display cover with realistic haptic texture and manufacturing method thereof.

### 2. Description of Related Art

Electronic display modules, such as screens of smartphones and dashboards of scooters or cars, are usually equipped with a clear glass cover for protecting the modules form direct impact or attrition.

Such a clear glass cover, however, is conventionally a plain and planar glass sheet without any esthetic or structural adornments or decorations, and simply shows the blank screen when the electronic display module it protects is not in operation. This prevents the conventional glass cover from providing added value in terms of visual esthetics and operative experience and thus limits its qualitative value.

### SUMMARY OF THE INVENTION

A primary objective of the present invention is to address the issues of conventional glass covers of electronic display modules about bald appearance and poor texture.

To achieve the foregoing objective, one embodiment of the present invention provides a glass display cover with realistic haptic texture. The glass display cover is for being installed at one side of a display module, and it comprises a glass substrate, a pattern layer, a pattern-highlighting layer, and a textured layer. The glass substrate has a first surface facing the side of the display module and a second surface reverse to the first surface. A display light emitted by the display module is allowed to pass through the glass substrate to be seen by users. The pattern layer is formed by stacking a plurality of color layers on the first surface. The pattern layer comprises a pattern area and a background area. The pattern-highlighting layer is formed on a side of the pattern layer that faces away from the first surface. The pattern-highlighting layer is made of a mixture comprising a white ink and a diluent. The textured layer is formed on the second surface and is made of a solvent material doped with a plurality of particles.

Another embodiment of the present invention provides a manufacturing method of a glass display cover with realistic haptic texture. The method comprises steps of: formation of a pattern layer: printing and stacking a plurality of color layers on a first surface of a glass substrate so as to form the pattern layer that comprises a pattern area and a background area; formation of a pattern-highlighting layer: printing the pattern-highlighting layer on a side of the pattern layer that faces away from the first surface, wherein the pattern-highlighting layer is made of a mixture of a white ink and a diluent; and formation of a textured layer: printing the textured layer on a second surface of the glass substrate, wherein the textured layer is made of a solvent material doped with a plurality of particles.

A haptic texture portion and the particles render the surface of the textured layer uneven, and allow the textured layer to provide realistic haptic texture corresponding to the pattern presented by the pattern layer. The disclosed glass display cover with realistic haptic texture enhances user experience with not only visual esthetics but also realistic haptic impression, thereby having added qualitative value.

### BRIEF DESCRIPTION OF THE DRAWINGS

FIG. 1 is an applied top view of a glass display cover with realistic haptic texture according to one embodiment of the present invention, showing that the pattern layer presents a particular pattern, such as a wood grain pattern.

FIG. 2 is a cross-sectional view taken along Line A-A of FIG. 1, illustrating the structure of the glass display cover.

FIG. 3 is another applied top view of the glass display cover, showing that the pattern layer presents a particular pattern, such as a wood grain pattern, while the display module displays information.

FIG. 4 is a flowchart of a manufacturing method of a glass display cover with realistic haptic texture according to another embodiment of the present invention.

### DETAILED DESCRIPTION OF THE INVENTION

The following preferred embodiments when read with the accompanying drawings are made to clearly exhibit the above-mentioned and other technical contents, features and effects of the present invention. Through the exposition by means of the specific embodiments, people would further understand the technical means and effects the present invention adopts to achieve the above-indicated objectives. However, the accompanying drawings are intended for reference and illustration, but not to limit the present invention and are not made to scale.

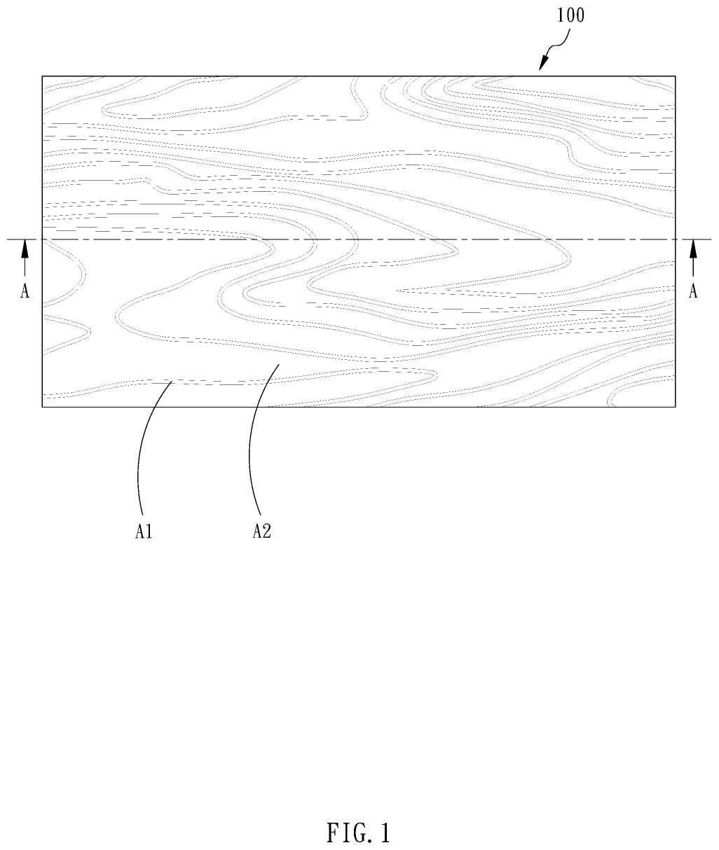

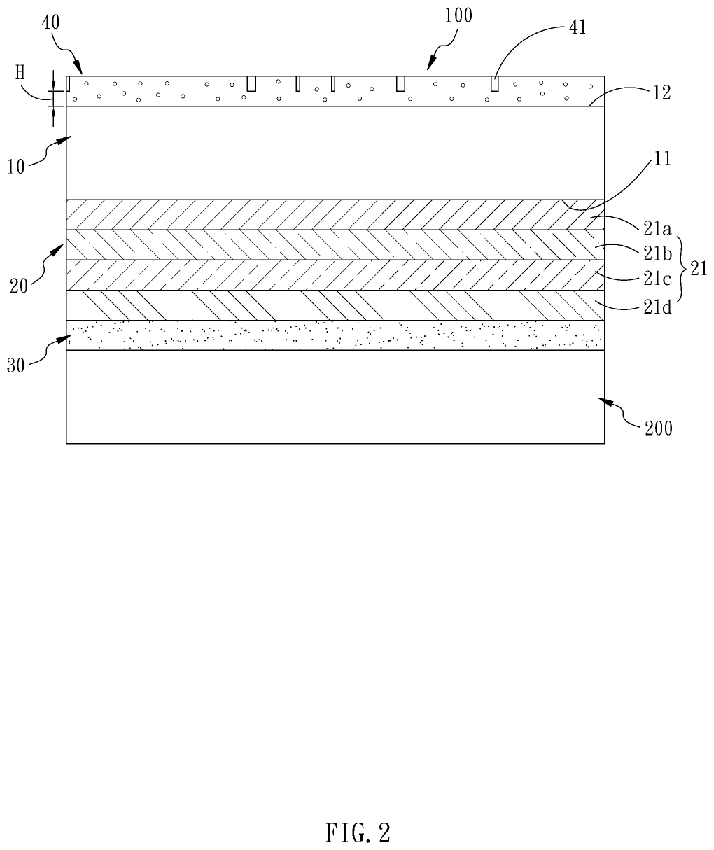

Referring to FIG. 1 through FIG. 3, in one embodiment of the present invention, a glass display cover with realistic haptic texture 100 is for being installed at one side of a display module 200. The glass display cover with realistic haptic texture 100 comprises a glass substrate 10, a pattern layer 20, a pattern-highlighting layer 30, and a textured layer 40. The display module 200 displays information for users to see. In an example where the display module 200 is a dashboard in a car, the display module 200 serves to show car-related information to a driver as the user. In FIG. 2, for better showing the structural relationship among the glass substrate 10, the pattern layer 20, the pattern-highlighting layer 30, and the textured layer 40, these components are not made to scale with respect to the display module 200. In fact, the thickness of each of the pattern layer 20, the pattern-highlighting layer 30, and the textured layer 40 is much smaller than that of the display module 200.

The glass substrate 10 is installed at one side of the display module 200 and faces the display module 200 with a first surface 11. The glass substrate 10 has a second surface 12 that faces away from the display module 200. The display module 200 emits a display light, and the display light passes through the glass substrate 10 to be seen by users so that the users can see the information displayed by the display module 200.

The pattern layer 20 is formed by a plurality of color layers 21 stacked on the first surface 11. The pattern layer 20 comprises a pattern area A1 and a background area A2. As shown in FIG. 1 through FIG. 3, in the present embodiment, the pattern area A1 is where a wood grain pattern formed on the pattern layer 20, and the background area A2 is the part of the pattern layer 20 not covered by the pattern of the pattern area A1.

As shown in FIG. 1 through FIG. 3, in the present embodiment, the color layer 21 is formed on the first surface 11 by means of screen printing or inkjet printing. The color layers 21 are selected from the group consisting of a yellow layer 21a, a magenta layer 21b, a cyan layer 21c, and a black layer 21d, and the color layers 21 are stacked in the order of the yellow layer 21a, the magenta layer 21b, the cyan layer 21c, and the black layer 21d. The pattern layer 20 composed of the stacked color layers 21 serves to present particular patterns and colors (such as the wood grain pattern in the pattern area A1 of FIG. 1) at the glass substrate 10, and enables the display module 200 to show information with variable visual effects.

In the present embodiment, the pattern layer 20 may have a visible light transmission of between 15% and 50%, such as 15%, 16%, 17%, 18%, 19%, 20%, 21%, 22%, 23%, 24%, 25%, 26%, 27%, 28%, 29%, 30%, 31%, 32%, 33%, 34%, 35%, 36%, 37%, 38%, 39%, 40%, 41%, 42%, 43%, 44%, 45%, 46%, 47%, 48%, 49%, or 50%, so that the glass substrate 10 can show the pattern without hindering the users from reading the information displayed by the display module 200. In other embodiments of the present invention, the color layers 21 may be of any combination of colors in any number and in any order depending on practical needs. For example, the yellow layer 21a may be cancelled, or the magenta layer 21b may be made duplicate, or the order of the cyan layer 21c and the black layer 21d may be reversed.

The pattern-highlighting layer 30 is provided at the side of the pattern layer 20 facing away from the first surface 11. The pattern-highlighting layer 30 is made of a mixture of a white ink and a diluent. In the present embodiment, the white ink accounts for 10% to 40% of the weight percentage of the pattern-highlighting layer 30, such as 10%, 12%, 14%, 16%, 18%, 20%, 22%, 24%, 26%, 28%, 30%, 32%, 34%, 36%, 38%, or 40%. Thereby, the pattern-highlighting layer 30 is such translucent that both highlighting the pattern shown by the pattern layer 20 and manifesting the information displayed by the display module 200 can be achieved. Therein, if the white ink accounts for less than 10% of the weight percentage of the pattern-highlighting layer 30, the resulting pattern-highlighting layer 30 would dull the glass display cover 100 and decrease the resulting display contrast, leading to incapability to show the pattern presented by the pattern layer 20 clearly. If the white ink accounts for more than 40% of the weight percentage of the pattern-highlighting layer 30, the pattern-highlighting layer 30 would make the glass display cover 100 too opaque to allow the information displayed by the display module 200 to be read clearly.

The textured layer 40 is formed on the second surface 12 of the glass substrate 10. The textured layer 40 is made of a solvent material mixed with a plurality of particles. In the present embodiment, the textured layer 40 has an overall thickness of between 10 μm and 15 μm. The textured layer 40 is formed by means of screen printing, and has a sunken haptic texture portion 41. The haptic texture portion 41 is selectively in locational correspondence to the pattern area A1 or the background area A2. The haptic texture portion 41 has a thickness H (equal to the distance from the sunken part of the haptic texture portion 41 to the second surface 12 as shown in FIG. 2) that is of between 10 μm and 13 μm. Thereby, the haptic texture portion 41 may be aligned with the pattern area A1 or the background area A2 according to practical needs, so as to allow the textured layer 40 to provide variable haptic texture with the uneven surface. Moreover, the textured layer 40 is so thin that it is compatible to a glass cover that supports touch control.

In the present embodiment, the solvent material for making the textured layer 40 comprises 55% to 75% of a synthetic acrylic resin, 5% to 15% of ethylene glycol monobutyl ether, and 10% to 40% of diethylene glycol monobutyl ether. The solvent material containing the particles is applied on the second surface 12 and then cured by backing so as to form the textured layer 40 (with the ethers evaporated during the baking process). The textured layer 40 is matte clear in appearance and has a hardness not smaller than the pencil hardness of 9H. Advantageously, the textured layer 40 ensures clearness of images displayed by the display module 200 and is hard enough to be durable. Additionally, in other preferred embodiments, the solvent material comprises 65% of the synthetic acrylic resin, 10% of ethylene glycol monobutyl ether, and 25% of diethylene glycol monobutyl ether.

In the present embodiment, the particles account for 5% to 20% of the weight percentage of the textured layer 40. The particles are made of silicon dioxide and have a particle size not greater than 3 μm. The particles endow the textured layer 40 with desired roughness so that the textured layer 40 can give realistic haptic texture. Besides, existence of the particles contributes to desired anti-glare (AG) effect.

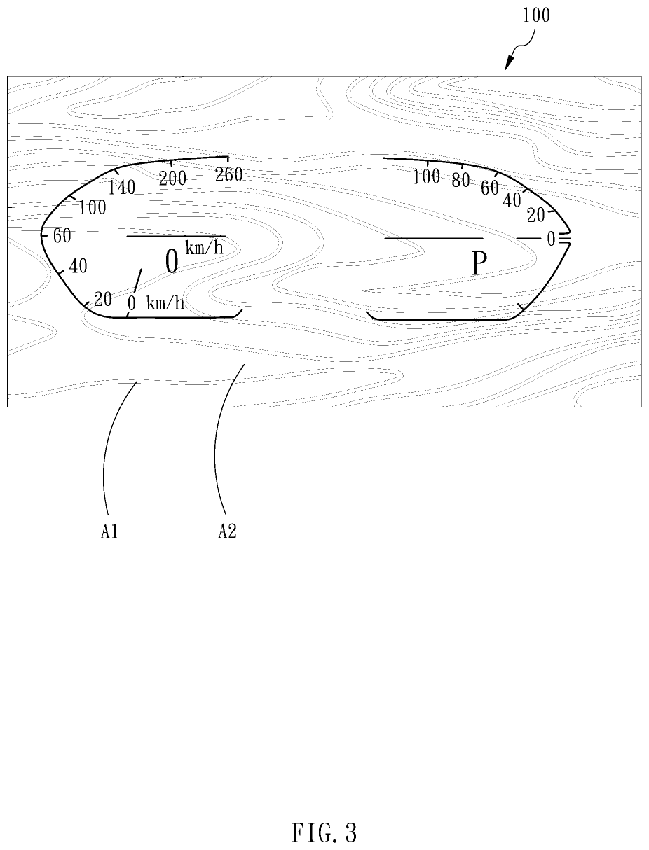

Referring to FIG. 1 through FIG. 3, in an example where the disclosed glass display cover 100 is applied to an automotive dashboard, when the display module 200 is idle from displaying information, the pattern layer 20 and the pattern-highlighting layer 30 reflect the ambient light and present a wood grain pattern that matches the car interior, so as to visually hide the dashboard in the car interior. Additionally, with the textured layer 40, the disclosed glass display cover 100 presents the haptic texture like the natural wood grain. When the display module 200 displays information, light from the display module 200 passes through the pattern layer 20 and the pattern-highlighting layer 30, and shows the information on the dashboard, as depicted in FIG. 3. Moreover, the disclosed glass display cover 100 is applicable to in-car decoration panels, such as those for hardware between the passenger seat and the windshield, for the center console, or for the doors, for users to see and touch with improved user experience.

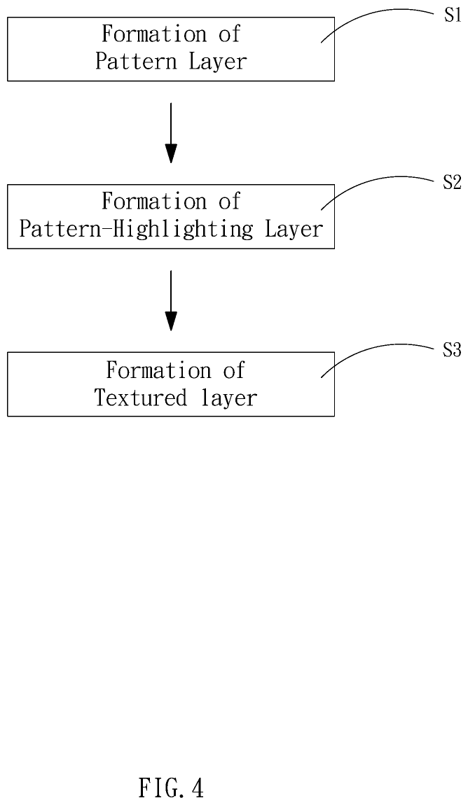

The present invention further provides a manufacturing method of the glass display cover with realistic haptic texture 100. The glass display cover with realistic haptic texture 100 is for being installed at one side of the display module 200. As shown in FIG. 2 and FIG. 4, the manufacturing method of the glass display cover 100 comprises the following steps.

A first step S1 is for formation of the pattern layer and comprises printing and stacking the plurality of color layers 21 on the first surface 11 of the glass substrate 10 so as to form the pattern layer 20 that comprises the pattern area A1 and the background area A2.

In the present embodiment, the color layers 21 are selected from the group consisting of the yellow layer 21a, the magenta layer 21b, the cyan layer 21c, and the black layer 21d. During the step S1 for formation of the pattern layer, the yellow layer 21a, the magenta layer 21b, the cyan layer 21c, and the black layer 21d are formed successively in order on the first surface 11 from the first surface 11 to the pattern-highlighting layer 30 by means of screen printing or inkjet printing, thereby forming the pattern layer 20.

In the present embodiment, the pattern layer 20 has a visible light transmission of between 15% to 50%, so that the glass substrate 10 can show the pattern without hindering the users from reading the information displayed by the display module 200. In other embodiments of the present invention, for performing the step S1, the color layers 21 may be of any combination of colors in any number and in any order depending on practical needs. For example, the yellow layer 21a may be cancelled, or the magenta layer 21b may be made duplicate, or the order of the cyan layer 21c and the black layer 21d may be reversed.

A second step S2 is for formation of the pattern-highlighting layer and comprises printing the pattern-highlighting layer 30 on the side of the pattern layer 20 facing away from the first surface 11, wherein the pattern-highlighting layer 30 is made of the mixture of the white ink and the diluent.

In the present embodiment, the white ink accounts for 10% to 40% of the weight percentage of the pattern-highlighting layer 30. Thereby, the pattern-highlighting layer 30 can manifest the information displayed by the display module 200 while highlighting the pattern shown by the pattern layer 20. Therein, if the white ink accounts for less than 10% of the weight percentage of the pattern-highlighting layer 30, the resulting pattern-highlighting layer 30 would dull the glass display cover 100 and decrease the resulting display contrast, leading to incapability to show the pattern presented by the pattern layer 20 clearly. If the white ink accounts for more than 40% of the weight percentage of the pattern-highlighting layer 30, the pattern-highlighting layer 30 would make the glass display cover 100 too opaque to allow the information displayed by the display module 200 to be read clearly.

A third step S3 is for formation of the textured layer and comprises printing the textured layer 40 on the second surface 12 of the glass substrate 10, wherein the textured layer 40 is made of the solvent material mixed with the particles. In the present embodiment, the overall thickness of the textured layer 40 is of between 10 μm and 15 μm. The textured layer 40 has the sunken haptic texture portion 41 that is in locational correspondence to the pattern area A1 or the background area A2. The haptic texture portion 41 has a thickness H of between 10 μm and 13 μm. Thereby, the haptic texture portion 41 may be aligned with the pattern area A1 or the background area A2 according to practical needs, so as to allow the textured layer 40 to provide variable haptic texture with the uneven surface. Moreover, the textured layer 40 is so thin that it is compatible to a glass cover that supports touch control.

In the present embodiment, the textured layer 40 is made by applying the solvent material mixed with particles on the second surface 12 by means of screen printing, and then baking to cure the solvent material so as to form the textured layer 40 on the second surface 12. The solvent material for making the textured layer 40 comprises 55% to 75% of the synthetic acrylic resin, 5% to 15% of ethylene glycol monobutyl ether, and 10% to 40% of diethylene glycol monobutyl ether. The textured layer 40 is matte clear in appearance and has a hardness not smaller than the pencil hardness of 9H. Advantageously, the textured layer 40 ensures clearness of images displayed by the display module 200 and is hard enough to be durable. Additionally, in other preferred embodiments, the solvent material comprises 65% of the synthetic acrylic resin, 10% of ethylene glycol monobutyl ether, and 25% of diethylene glycol monobutyl ether.

In the present embodiment, the particles account for 5% to 20% of the weight percentage of the textured layer 40. The particles are made of silicon dioxide and have a particle size not greater than 3 μm. The particles endow the textured layer 40 with desired roughness so that the textured layer 40 can give realistic haptic texture. Besides, existence of the particles contributes to desired anti-glare (AG) effect.

Thereby, the present invention provides the following advantages:

1. Due to existence of the haptic texture portion 41 and the particles, the textured layer 40 has an uneven surface that provides realistic haptic texture corresponding to the pattern presented by the pattern layer 20, so that the glass display cover 100 enhances user experience with realistic haptic impression, thereby having added qualitative value.

2. The pattern layer 20 presents particular patterns and colors (such as the wood grain pattern shown in FIG. 1 and FIG. 3) at the glass substrate 10, so as to accompany the information displayed by the display module 200 with matching visual effect, thereby enhancing esthetic and qualitative value of the glass display cover 100.

3. The surface of the textured layer 40 is uneven due to existence of the particles, and the particles distributed across the textured layer 40 scattering the incident light. Thereby, the textured layer 40 is anti-glare (AG) and advantageously reduces reflected glare caused by the glass substrate 10. Consequently, the pattern presented by the pattern layer 20 can be seen more clearly at the glass substrate 10. Additionally, the anti-glare nature of the textured layer 40 eliminates the need for additionally coating and this helps to reduce the manufacturing costs.

The present invention has been described with reference to the preferred embodiments and it is understood that the embodiments are not intended to limit the scope of the present invention. Moreover, as the contents disclosed herein should be readily understood and can be implemented by a person skilled in the art, all equivalent changes or modifications which do not depart from the concept of the present invention should be encompassed by the appended claims.

What is claimed is:

1. A glass display cover with realistic haptic texture for being installed at one side of a display module, the glass display cover comprising:
a glass substrate, being installed at one side of the display module, and having a first surface facing the side of the display module and a second surface facing away from the display module, so that a display light emitted by the display module is allowed to pass through the glass substrate to be seen by a user;
a pattern layer, being formed by a plurality of color layers stacked on the first surface, and comprising a pattern area and a background area;
a pattern-highlighting layer, being formed on one side of the pattern layer that faces away from the first surface, wherein the pattern-highlighting layer is made of a mixture of a white ink and a diluent; and
a textured layer, being formed on the second surface and made of a solvent material that is mixed with a plurality of particles.

2. The glass display cover of claim 1, wherein the textured layer has a thickness of between 10 μm and 15 μm.

3. The glass display cover of claim 1, wherein the textured layer comprises a sunken haptic texture portion that is selectively in locational correspondence to the pattern area or the background area.

4. The glass display cover of claim 1, wherein the solvent material comprises 55% to 75% of a synthetic acrylic resin, 5% to 15% of ethylene glycol monobutyl ether, and 10% to 40% of diethylene glycol monobutyl ether.

5. The glass display cover of claim 1, wherein the particles account for 5% to 20% of a weight percentage of the textured layer.

6. The glass display cover of claim 1, wherein the particles are made of silicon dioxide.

7. The glass display cover of claim 1, wherein each of the particles has a particle size that is not greater than 3 μm.

8. The glass display cover of claim 1, wherein the color layers are selected from a group consisting of a yellow layer, a magenta layer, a cyan layer and a black layer.

9. The glass display cover of claim 8, wherein the color layers include the yellow layer, the magenta layer, the cyan layer, and the black layer arranged successively from the first surface to the pattern-highlighting layer.

10. A manufacturing method of a glass display cover with realistic haptic texture, comprising steps of:
formation of a pattern layer: printing and stacking a plurality of color layers on a first surface of a glass substrate so as to form a pattern layer that comprises a pattern area and a background area;
formation of a pattern-highlighting layer: printing a pattern-highlighting layer on a side of the pattern layer that faces away from the first surface, wherein the pattern-highlighting layer is made of a mixture of a white ink and a diluent; and
formation of a textured layer: printing a textured layer on a second surface of the glass substrate, wherein the textured layer is made of a solvent material that is mixed with a plurality of particles.

11. The manufacturing method of claim 10, wherein the step for formation of the textured layer comprises applying the solvent material mixed with the particles on the second surface by means of screen printing, and then curing the solvent material by means of baking so as to form the textured layer.

12. The manufacturing method of claim 10, wherein the textured layer has a thickness of between 10 μm and 15 μm.

13. The manufacturing method of claim 10, wherein during the step for formation of the textured layer, the textured layer is formed with a sunken haptic texture portion that is locational correspondence to the pattern area or the background area.

14. The manufacturing method of claim 10, wherein the solvent material comprises 55% to 75% of a synthetic acrylic resin, 5% to 15% of ethylene glycol monobutyl ether, and 10% to 40% of diethylene glycol monobutyl ether.

15. The manufacturing method of claim 10, wherein the particles accounts for 5% to 20% of a weight percentage of the textured layer.

16. The manufacturing method of claim 10, wherein each of the particles has a particle size that is not greater than 3 μm.

17. The manufacturing method of claim 10, wherein the color layers are selected from a group consisting of a yellow layer, a magenta layer, a cyan layer and a black layer.

18. The manufacturing method of claim 17, wherein in the step for formation of the pattern layer, the color layers are such formed that the yellow layer, the magenta layer, the cyan layer, and the black layer are printed successively from the first surface to the pattern-highlighting layer.
